(19) United States
(12) Patent Application Publication
(10) Pub. No.: US 2024/0222091 A1
(43) Pub. Date: Jul. 4, 2024

(54) ELECTROSTATIC CHUCK AND PLASMA PROCESSING APPARATUS

(71) Applicant: Tokyo Electron Limited, Tokyo (JP)

(72) Inventor: Koei ITO, Kurokawa-gun (JP)

(73) Assignee: Tokyo Electron Limited, Tokyo (JP)

(21) Appl. No.: 18/606,213

(22) Filed: Mar. 15, 2024

Related U.S. Application Data
(63) Continuation of application No. PCT/JP2022/042673, filed on Nov. 17, 2022.

(30) Foreign Application Priority Data
Nov. 26, 2021 (JP) 2021-192399

(51) Int. Cl. H01J 37/32

(52) U.S. Cl. CPC H01J 37/32715; H01J 37/32082; H01J 2237/2007

(57) ABSTRACT

An electrostatic chuck includes a substrate support to support at least one of a substrate or an edge ring, an electrostatic electrode inside the substrate support to electrostatically clamp at least one of the substrate or the edge ring, and an electrode inside the substrate support and located on a plane different from a plane on which the electrostatic electrode is located. The substrate support has a through-hole extending through the substrate support from an upper surface of the substrate support to a lower surface of the substrate support. The electrode is at least partially located between the electrostatic electrode and the through-hole.

### CROSS REFERENCE TO RELATED APPLICATIONS

This application is a bypass continuation application of International Application No. PCT/JP2022/042673 having an international filing date of Nov. 17, 2022, and designating the United States, the international application being based upon and claiming the benefit of priority from Japanese Patent Application No. 2021-192399, filed on Nov. 26, 2021, the entire contents of each are incorporated herein by reference.

### FIELD

The disclosure relates to an electrostatic chuck (ESC) and a plasma processing apparatus.

### BACKGROUND

An ESC has gas supply holes for supplying a heat transfer gas introduced from the back surface of the ESC to the upper surface of the ESC to cool a wafer. For example, Patent Literature 1 describes a substrate support including an ESC to support a wafer, an electrostatic electrode located in the ESC, and gas supply holes that are open in the upper surface of the ESC to connect with a heat transfer gas channel extending through the ESC from its upper surface to the lower surface.

### CITATION LIST

### Patent Literature

Patent Literature 1: Japanese Unexamined Patent Application Publication No. 2021-82788

### SUMMARY

### Technical Problem

One or more aspects of the disclosure are directed to a technique for preventing or reducing occurrence of abnormal discharge in gas supply holes for supplying a heat transfer gas.

### Solution to Problem

An electrostatic chuck according to an aspect of the disclosure includes a substrate support to support at least one of a substrate or an edge ring, an electrostatic electrode inside the substrate support to electrostatically clamp at least one of the substrate or the edge ring, and an electrode inside the substrate support and located on a plane different from a plane on which the electrostatic electrode is located. The substrate support has a through-hole extending through the substrate support from an upper surface of the substrate support to a lower surface of the substrate support. The electrode is at least partially located between the electrostatic electrode and the through-hole.

### Advantageous Effects

The technique according to the above aspect of the disclosure can prevent or reduce occurrence of abnormal discharge in gas supply holes for supplying a heat transfer gas.

### BRIEF DESCRIPTION OF DRAWINGS

FIG. 1 is a diagram of a plasma processing system according to one embodiment.

FIG. 2 is a diagram of a plasma processing apparatus with an example structure according to one embodiment.

FIGS. 3A to 3C are diagrams of an electrostatic chuck (ESC) according to one embodiment, showing its electrode structure.

FIG. 4 is a sectional view taken along line B-B in FIG. 3B.

FIG. 5 is a longitudinal sectional view of an ESC according to one embodiment, showing its electrode structure.

FIG. 6A is a diagram of a second electrode portion in a first modification of one embodiment.

FIG. 6B is a diagram of a second electrode portion in a second modification of one embodiment.

FIG. 6C is a diagram of a second electrode portion in a third modification of one embodiment.

### DETAILED DESCRIPTION

One or more embodiments of the disclosure will now be described with reference to the drawings. Like reference numerals denote like components in the drawings. Such components may not be described repeatedly.

The directions described herein using terms such as parallel, right-angled, orthogonal, horizontal, perpendicular, vertical, and lateral permit deviations with degrees that can maintain the advantageous effects of the embodiments. Corners herein may be rounded, in addition to being right-angled. Being parallel, right-angled, orthogonal, horizontal, perpendicular, and circular may include being substantially parallel, substantially right-angled, substantially orthogonal, substantially horizontal, substantially perpendicular, and substantially circular.

### Plasma Processing System

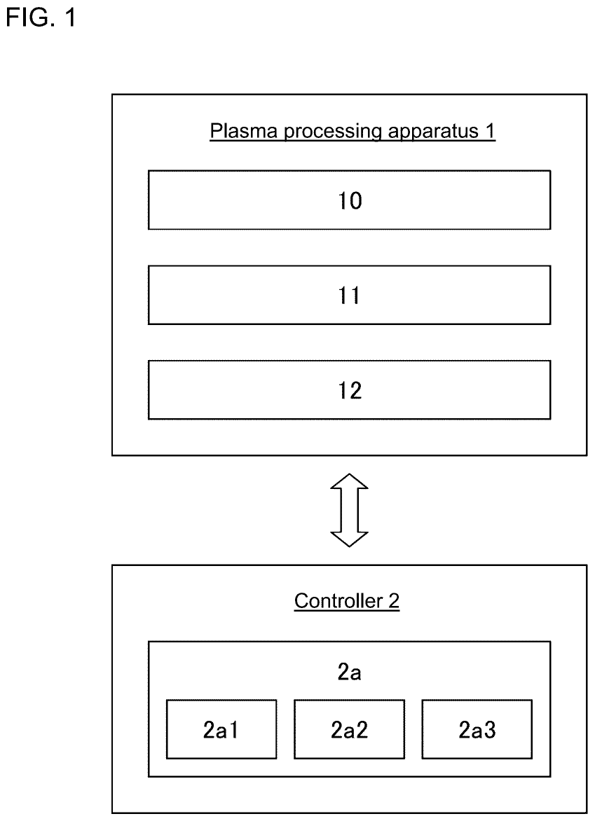

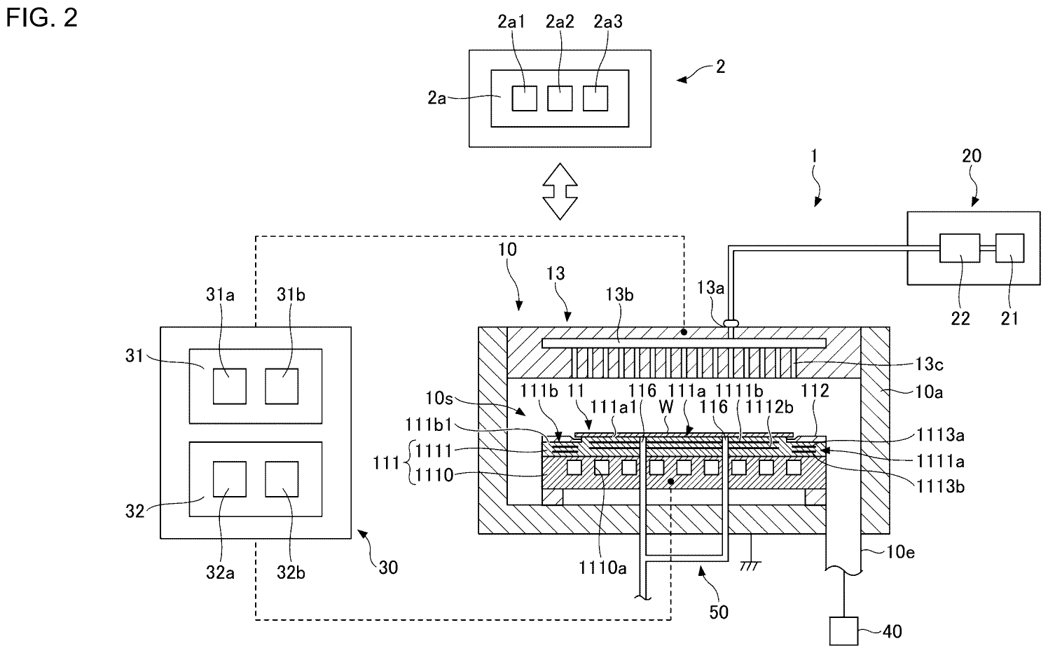

FIG. 1 is a diagram of a plasma processing system with an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space 10s (refer to FIG. 2). The plasma processing chamber 10 has at least one gas inlet 13a (refer to FIG. 2) for receiving at least one process gas supplied into the plasma processing space 10s and at least one gas outlet 10e (refer to FIG. 2) for discharging the gas from the plasma processing space 10s. The gas inlet 13a connects to a gas supply 20 (described later). The gas outlet 10e connects to an exhaust system 40 (described later). The substrate support 11 is located in the plasma processing space 10s and has a substrate support surface for supporting a substrate W (refer to FIG. 2).

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

An example structure of a capacitively coupled plasma processing apparatus as an example of the plasma processing apparatus 1 will now be described. FIG. 2 is a diagram of the capacitively coupled plasma processing apparatus with an example structure.

The capacitively coupled plasma processing apparatus 1 includes the plasma processing chamber 10, the gas supply 20, a power supply 30, and the exhaust system 40. The plasma processing apparatus 1 also includes the substrate support 11 and a gas inlet unit. The gas inlet unit allows at least one process gas to be introduced into the plasma processing chamber 10. The gas inlet unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has the plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 (substrate support) includes a central portion 111a for supporting the substrate W and an annular portion 111b for supporting the ring assembly 112. The substrate W is, for example, a wafer. The annular portion 111b of the body 111 surrounds the central portion 111a of the body 111 as viewed in plan. The substrate W is placed onto the central portion 111a of the body 111. The ring assembly 112 is placed onto the annular portion 111b of the body 111 to surround the substrate W on the central portion 111a. Thus, the central portion 111a is also referred to as a substrate support surface for supporting the substrate W. The annular portion 111b is also referred to as a ring support surface for supporting the ring assembly 112. The substrate support surface and the ring support surface are examples of a support surface to support at least one of the substrate W or an edge ring (described later) in the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. A ceramic member 1111a includes the central portion 111a. The ESC 1111 includes, in the central portion 111a, the ceramic member 1111a and an electrostatic electrode 1111b located inside the ceramic member 1111a. The annular portion 111b may be included in a separate member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF electrode coupled to an RF power supply 31 (described later), at least one DC electrode coupled to a DC power supply 32 (described later), or both the RF electrode and the DC electrode may be located inside the ceramic member 1111a. In this case, the RF electrode, the DC electrode, or both the electrodes serve as lower electrodes. When at least one of a bias RF signal or a DC signal (described later) is provided to at least one RF electrode, to at least one DC electrode, or to both the electrodes, at least one of the RF electrode or the DC electrode is also referred to as a bias electrode. An electrode 1112b is embedded in the ESC 1111. The electrode 1112b is located below the electrostatic electrode 1111b and includes a first electrode portion substantially parallel to the electrostatic electrode 1111b. The conductive member in the base 1110 and at least one RF electrode, the conductive member and at least one DC electrode, or the conductive member and both the electrodes may serve as multiple lower electrodes. The electrostatic electrode 1111b may also serve as a lower electrode. Thus, the substrate support 11 includes at least one lower electrode.

The ring assembly 112 includes one or more annular members. In one embodiment, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate W to a target temperature. The temperature control module may include a heater, a heat transfer medium, a channel 1110a, or a combination of these. The channel 1110a allows a heat transfer fluid such as brine or gas to flow. In one embodiment, the channel 1110a is defined in the base 1110, and one or more heaters are located in the ceramic member 1111a in the ESC 1111. The electrode 1112b may be one or more heater electrodes. The substrate support 11 includes a heat transfer gas supply 50 to supply a heat transfer gas into a space between the back surface of the substrate W and the central portion 111a. The heat transfer gas supply 50 supplies the heat transfer gas into the space between the back surface of the substrate W and the central portion 111a through gas supply holes 116 in the ESC 1111.

In one embodiment, the ceramic member 1111a also includes the annular portion 111b. The ESC 1111 may include, in the annular portion 111b, the ceramic member 1111a and an electrostatic electrode 1113a located inside the ceramic member 1111a. The ESC 1111 may include, below the electrostatic electrode 1113a, an electrode 1113b including a first electrode portion substantially parallel to the electrostatic electrode 1113a. The electrode 1113b is an example of a bias electrode.

The shower head 13 introduces at least one process gas from the gas supply 20 into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas inlet unit may include one or more side gas injectors (SGIs) installed in one or more openings in the side wall 10a.

The gas supply 20 may include at least one gas source 21 and at least one flow controller 22. In one embodiment, the gas supply 20 allows supply of at least one process gas from the corresponding gas source 21 to the shower head 13 through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the plasma to the substrate W.

In one embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated source RF signal or the generated multiple source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated bias RF signal or the generated multiple bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms. In one embodiment, a waveform generator for generating a sequence of voltage pulses based on DC signals is located between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, the gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

### Electrode Structure

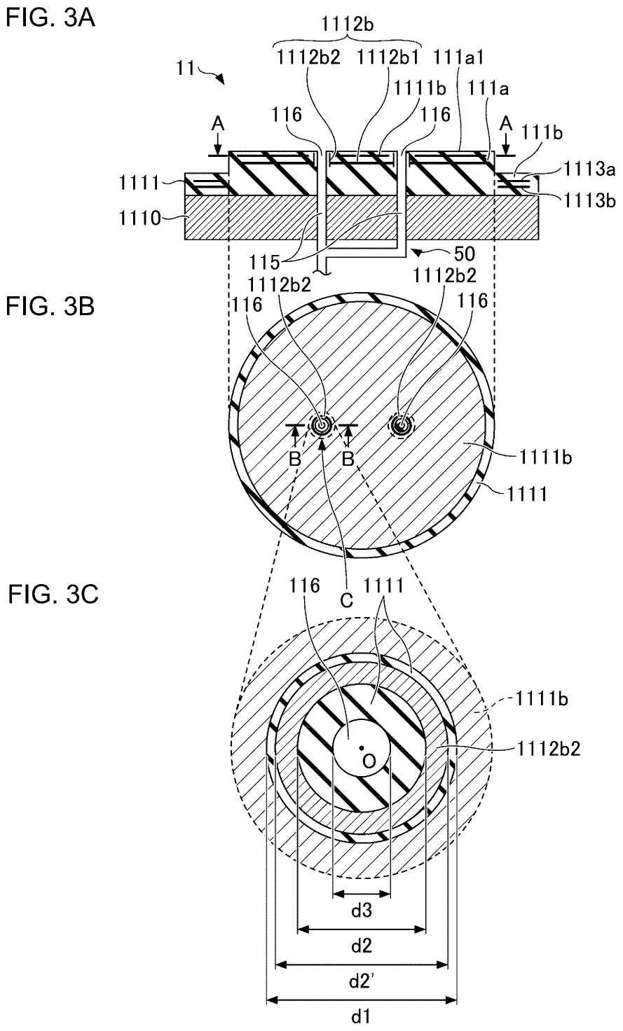

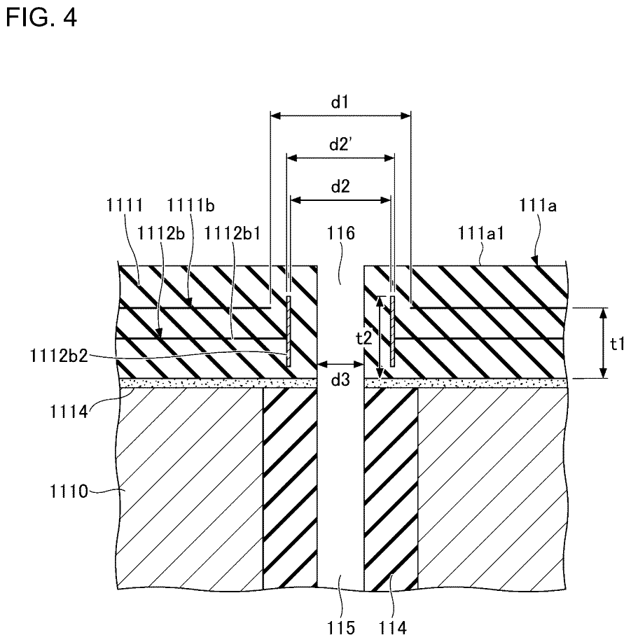

FIGS. 3A to 3C are diagrams of the ESC 1111 according to one embodiment showing its electrode structure in detail. FIG. 3A is a schematic longitudinal sectional view of the substrate support 11. FIG. 3B is a cross-sectional view taken along line A-A in FIG. 3A. FIG. 3C is an enlarged view of area C (in a dotted frame) in FIG. 3B. FIG. 4 is a cross-sectional view taken along line B-B in FIG. 3B, showing the electrode structure around the gas supply hole 116 in the ESC 1111 in an enlarged manner. The electrode structure in one or more embodiments of the disclosure prevents or reduces occurrence of abnormal discharge in the internal spaces of the gas supply holes 116.

As shown in FIGS. 2 to 4, the ESC 1111 includes the electrostatic electrode 1111b embedded substantially horizontally with respect to a support surface 111a1 of the central portion 111a. The electrostatic electrode 1111b is a film electrode and is formed from a conductive material. Examples of the conductive material include metal and a conductive ceramic material. The electrostatic electrode 1111b is substantially circular and has a smaller diameter than the support surface 111a1.

The ESC 1111 has the gas supply holes 116. The base 1110 has heat transfer gas channels 115. Each heat transfer gas channel 115 is an insulating sleeve 114 (refer to FIG. 4) with a through passage fitted into a through-hole in the base 1110. The gas supply holes 116 extend through the ESC 1111 and an adhesive layer 1114, and connect with the respective heat transfer gas channels 115 in the vertical direction. The heat transfer gas channels 115 extend through the base 1110, and allow a heat transfer gas such as a helium (He) gas supplied from the heat transfer gas supply 50 (refer to FIGS. 2 and 3A) to flow into the respective gas supply holes 116. The heat transfer gas is supplied through the gas supply holes 116 into the space between the back surface of the substrate W and the support surface 111a1 of the central portion 111a supporting the substrate W. The ESC 1111 may have more than two gas supply holes 116, and the base 1110 may have more than two heat transfer gas channels 115, although two gas supply holes 116 are illustrated in the example in FIG. 3B. Any number of gas supply holes 116 and heat transfer gas channels 115 may be arranged in any manner.

The structure may further include a gas supply hole and a heat transfer gas channel (both not shown) to supply a heat transfer gas into a space between the back surface of the edge ring or the ring assembly 112 and a support surface 111b1 (refer to FIGS. 2 and 3A) of the annular portion 111b supporting the edge ring or the ring assembly 112. The gas supply hole and the heat transfer gas channel (both not shown) extend through the electrostatic electrode 1113a and the electrode 1113b below the electrostatic electrode 1113a in the annular portion 111b. The electrostatic electrode 1113a may correspond to the electrostatic electrode 1111b, and the electrode 1113b may correspond to the electrode 1112b and may have an electrode structure (described later) including a first electrode portion and a second electrode portion. More specifically, the gas supply hole and the heat transfer gas channel may be located in at least one of the central portion 111a or the annular portion 111b.

The electrode 1112b is embedded in the ESC 1111. The electrode 1112b is on a plane different from a plane on which the electrostatic electrode 1111b is located, and partly between the electrostatic electrode 1111b and the gas supply holes 116.

The electrode 1112b may be an RF electrode to which a bias RF signal is provided. The electrode 1112b may be a DC electrode to which a DC signal is provided. The electrode 1112b may be a bias electrode as at least one RF electrode, at least one DC electrode, or both the electrodes to which at least one of the bias RF signal or the DC signal is provided. The electrode 1112b may be a heater electrode to which an AC signal or a DC signal is provided. The bias RF signal may include a rectangular bias RF signal (pulsed bias RF signal).

The electrode 1112b includes a first electrode portion 1112b1. The first electrode portion 1112b1 is a film electrode and is formed from a conductive material. The first electrode portion 1112b1 is located below the electrostatic electrode 1111b and is substantially parallel to the electrostatic electrode 1111b. In some embodiments, the first electrode portion 1112b1 located on a plane different from a plane on which the electrostatic electrode 1111b is located may not be substantially parallel to the electrostatic electrode 1111b.

The first electrode portion 1112b1 is substantially circular, and has a diameter smaller than the diameter of the support surface 111a1 and substantially the same as the diameter of the electrostatic electrode 1111b. In some embodiments, the first electrode portion 1112b1 may not be substantially circular, and may have one of various shapes. For the electrode 1112b being a heater electrode, for example, the first electrode portion 1112b1 may be divided into multiple zones and may have a different shape for each zone.

The electrostatic electrode 1111b and the electrode 1112b have holes through which the gas supply holes 116 extend. The electrode 1112b further includes second electrode portions 1112b2 electrically coupled to the first electrode portion 1112b1. The second electrode portions 1112b2 substantially cylindrically surround the respective gas supply holes 116 along the inner circumferences of the respective holes in the first electrode portion 1112b1. The second electrode portions 1112b2 may not be substantially cylindrical when surrounding the respective gas supply holes 116 as viewed in plan.

The second electrode portions 1112b2 are electrically coupled to the first electrode portion 1112b1 in a substantially perpendicular manner. The second electrode portions 1112b2 extend upward from the first electrode portion 1112b1 in a substantially perpendicular manner. In some embodiments, the second electrode portions 1112b2 may not be located substantially perpendicularly, and may be obliquely coupled to the first electrode portion 1112b1. Each second electrode portion 1112b2 may be inclined at an angle that causes its lower portion to have a larger diameter than its upper portion or at an angle that causes its lower portion to have a smaller diameter than its upper portion. A clearance may be left between the first electrode portion 1112b1 and each second electrode portion 1112b2. In this case, an RF signal propagates between the first electrode portion 1112b1 and the second electrode portions 1112b2 through capacitive coupling.

Each second electrode portion 1112b2 may have a uniform thickness or different thicknesses in the circumferential direction. For example, each second electrode portion 1112b2 may have a smooth inner surface, a curved inner surface, a stepped inner surface, or an uneven inner surface. Similarly, each second electrode portion 1112b2 may have a smooth outer surface, a curved outer surface, a stepped outer surface, or an uneven outer surface.

Referring to FIGS. 3A to 4, each second electrode portion 1112b2 in the electrode 1112b is located between the electrostatic electrode 1111b and the corresponding gas supply hole 116. Each gas supply hole 116 has a central axis including its center O, which is aligned with the central axis of the corresponding second electrode portion 1112b2 and the central axis of the corresponding hole in the electrostatic electrode 1111b.

When the gas supply hole 116 is a cylindrical hole extending vertically, the gas supply hole 116 has a diameter d3. When the gas supply hole 116 is not a cylindrical hole extending vertically, d3 is the shortest distance between two points on the inner surface. For example, when the gas supply hole 116 has an elliptical cross section, d3 is the minor axis of the gas supply hole 116.

The second electrode portion 1112b2 has an inner diameter (diameter of the inner surface) d2. When the second electrode portion 1112b2 is not substantially cylindrical, d2 is the shortest distance between two points facing each other on the inner surface of the second electrode portion 1112b2. The electrostatic electrode 1111b has the holes through which the respective gas supply holes 116 extend. The holes have a diameter d1. When each hole in the electrostatic electrode 1111b is not a perfect circle, d1 is the shortest distance between two points facing each other on the circumference of the hole in the electrostatic electrode 1111b. The electrode structure in one or more embodiments of the disclosure satisfies the condition of d3<d2<d1.

The second electrode portion 1112b2 has an outer diameter (diameter of the outer surface) d2′. The electrode structure in one or more embodiments of the disclosure satisfies the condition of d3<d2<d2′<d1.

A distance t2 between the upper end of the second electrode portion 1112b2 and the lower surface of the ESC 1111 is larger than or equal to a distance t1 between the electrostatic electrode 1111b and the lower surface of the ESC 1111. The second electrode portion 1112b2 extends to have its upper end upward from the first electrode portion 1112b1 to satisfy t2≥t1. The second electrode portion 1112b2 can thus extend to a level high enough to hide the electrostatic electrode 1111b as viewed from the gas supply hole 116.

The second electrode portion 1112b2 extends downward from the lower surface of the first electrode portion 1112b1 perpendicularly to the first electrode portion 1112b1. In some embodiments, the second electrode portion 1112b2 may not extend to have its lower end downward from the lower surface of the first electrode portion 1112b1. In other words, the second electrode portion 1112b2 may have its lower end on the same level as the lower surface of the first electrode portion 1112b1.

### Effects of Electrode Structure

In a known electrode structure, the electrode 1112b includes the first electrode portion 1112b1 and includes no second electrode portion 1112b2. In this case, in response to a DC voltage applied to the electrostatic electrode 1111b, an electric field is generated around the electrostatic electrode 1111b by the DC voltage applied to the electrostatic electrode 1111b. The electric field may partially leak into each gas supply hole 116, thus producing a voltage (generating a potential difference) in the gas supply hole 116. As the voltage in the gas supply hole 116 increases, discharge is more likely to occur in the internal space of the gas supply hole 116 with Paschen's law. With Paschen's law, the breakdown voltage is proportional to the product of the pressure and the distance between the electrodes. Discharge starts in the internal space of the gas supply hole 116 when the voltage in the gas supply hole 116 is greater than the breakdown voltage that is proportional to p×d defined by Paschen's law, where p is the pressure in the gas supply hole 116, and d is the diameter d1 of the hole in the electrostatic electrode 1111b. Abnormal discharge may then occur in the gas supply hole 116.

In the electrode structure in one or more embodiments of the disclosure, the electrode 1112b includes the first electrode portion 1112b1 and the second electrode portions 1112b2. Each second electrode portion 1112b2 is located along the inner circumference of the corresponding hole defined in the first electrode portion 1112b1 to have the corresponding gas supply hole 116 extending through the hole. The second electrode portions 1112b2 can thus shield the internal spaces of the respective gas supply holes 116 from the electric field generated around the electrostatic electrode 1111b in response to a DC voltage applied to the electrostatic electrode 1111b. In other words, the second electrode portions 1112b2 serve as shields to reduce the likelihood that any potential difference greater than or equal to the breakdown voltage is generated in the respective gas supply holes 116.

In the electrode structure shown in FIGS. 3A to 4, the second electrode portions 1112b2 and the electrostatic electrode 1111b are arranged with respect to the gas supply holes 116 to satisfy the condition of d3<d2<d1 and the condition of t2≥t1. More specifically, the inner diameter d2 of the second electrode portion 1112b2 is larger than the diameter d3 of the gas supply hole 116, and the diameter d1 of the hole in the electrostatic electrode 1111b is larger than the inner diameter d2 of the second electrode portion 1112b2. The distance t2 between the upper end of the second electrode portion 1112b2 and the lower surface of the ESC 1111 is larger than or equal to the distance t1 between the electrostatic electrode 1111b and the lower surface of the ESC 1111.

With the condition of d3<d2<d1 being satisfied, each second electrode portion 1112b2 is located between the corresponding gas supply hole 116 and the electrostatic electrode 1111b, and is not exposed to the internal space of the corresponding gas supply hole 116. With the condition of t2≥t1 being satisfied, each second electrode portion 1112b2 extends around the corresponding gas supply hole 116 to a level high enough to hide the electrostatic electrode 1111b as viewed from the corresponding gas supply hole 116.

The second electrode portions 1112b2 surround the respective gas supply holes 116 to a level higher than or equal to the electrostatic electrode 1111b, and can thus protect the respective gas supply holes 116. In other words, the second electrode portions 1112b2 prevent or reduce leakage of the electric field from the electrostatic electrode 1111b into the respective gas supply holes 116. This causes the potential difference in each gas supply hole 116 to be smaller than the breakdown voltage defined by Paschen's Law. The structure thus prevents or reduces occurrence of abnormal discharge in the gas supply holes 116. Each second electrode portion 1112b2 causes the potential difference in the corresponding gas supply hole 116 to be smaller, thus allowing a larger discharge margin between the potential difference and the breakdown voltage. This allows a higher-pressure heat transfer gas to be introduced into the gas supply holes 116 without causing abnormal discharge, allowing more effective cooling for the substrate W.

Other Electrode Structures

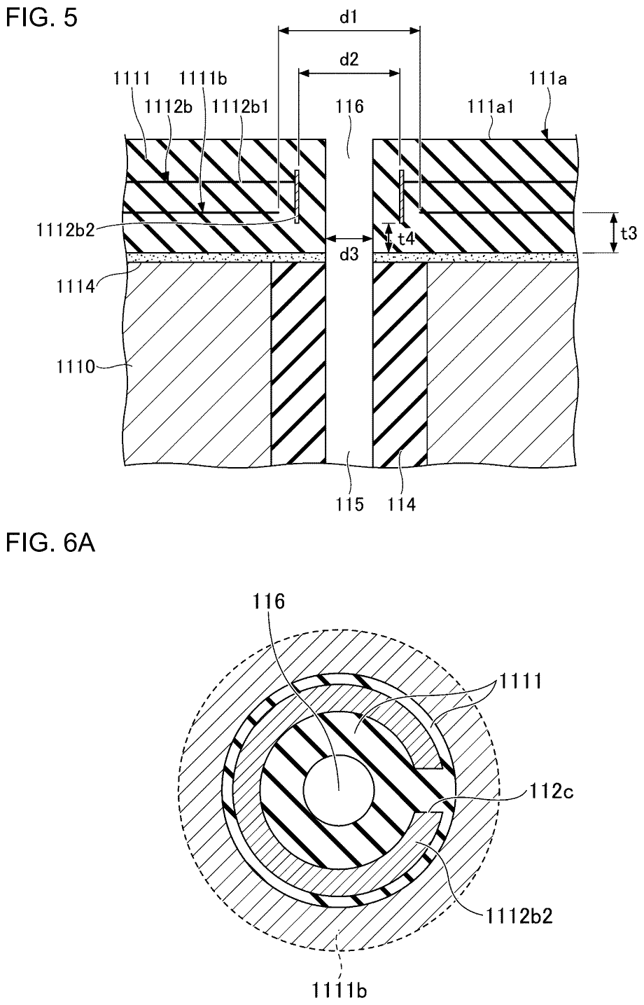

In the example described with reference to FIGS. 3A to 4, the electrode structure prevents or reduces occurrence of abnormal discharge in the gas supply holes 116 for supplying a heat transfer gas into the space between the back surface of the substrate W and the central portion 111a. The electrode structure is not limited this, and the electrode structure shown in FIG. 5 may be used to prevent or reduce occurrence of abnormal discharge in the gas supply holes 116. FIG. 5 is a longitudinal sectional view of an ESC 1111 according to one embodiment, showing another example electrode structure.

The electrode structure differs from the electrode structure in FIG. 3 in that the electrostatic electrode 1111b and the electrode 1112b are vertically inverted. In the electrode structure shown in FIG. 5, the electrostatic electrode 1111b is located closer to the base 1110 than the electrode 1112b, and the electrode 1112b is located above the ESC 1111.

The distance between the lower end of the second electrode portion 1112b2 and the lower surface of the ESC 1111 is indicated with t4. The distance between the lower end of the electrostatic electrode 1111b and the lower surface of the ESC 1111 is indicated with t3.

In the electrode structure shown in FIG. 5, the second electrode portion 1112b2 and the electrostatic electrode 1111b are arranged with respect to the gas supply hole 116 to satisfy the condition of d3<d2<d1 and the condition of t4≤t3. More specifically, the inner diameter d2 of the second electrode portion 1112b2 is larger than the diameter d3 of the gas supply hole 116, and the diameter d1 of the hole in the electrostatic electrode 1111b is larger than the inner diameter d2 of the second electrode portion 1112b2. The distance t4 between the lower end of the second electrode portion 1112b2 and the lower surface of the ESC 1111 is less than or equal to the distance t3 between the electrostatic electrode 1111b and the lower surface of the ESC 1111.

With the condition of d3<d2<d1 being satisfied, the second electrode portion 1112b2 is located between the gas supply hole 116 and the electrostatic electrode 1111b without being exposed to the gas supply hole 116. With the condition of t4≤t3 being satisfied, the second electrode portion 1112b2 extends around the gas supply hole 116 to a level high enough to hide the electrostatic electrode 1111b as viewed from the gas supply hole 116.

In this electrode structure, the second electrode portion 1112b2 serves as a shield to prevent leakage of the electric field generated around the electrostatic electrode 1111b in response to a DC voltage applied to the electrostatic electrode 1111b into the internal space of the gas supply hole 116. The structure can thus produce the same effects as the electrode structure shown in FIGS. 3A to 4. In other words, the structure can prevent or reduce occurrence of abnormal discharge in the gas supply holes 116.

### Modifications of Second Electrode Portion

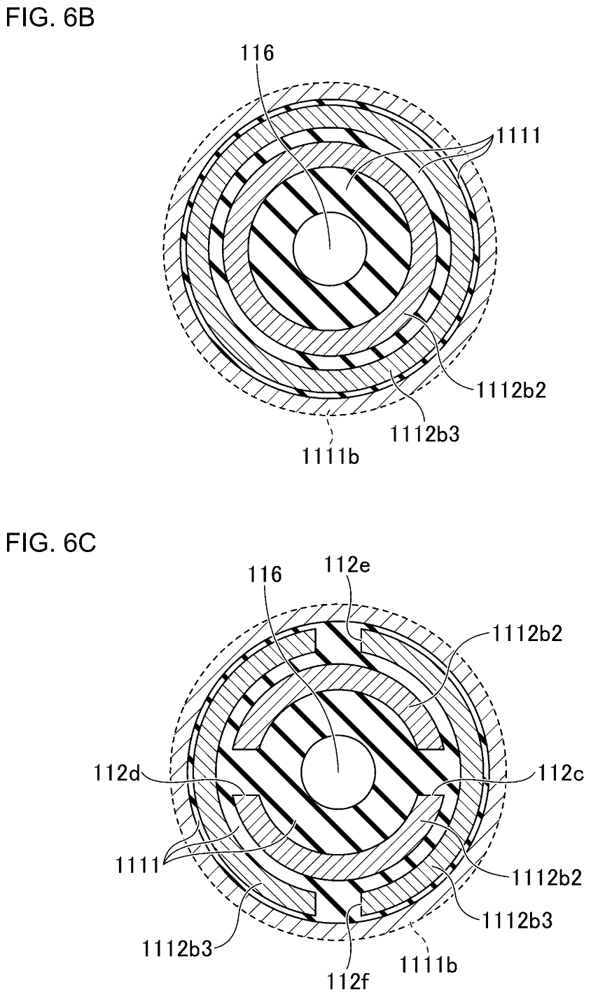

A second electrode portion in modifications will be described with reference to FIGS. 6A to 6C. FIGS. 6A to 6C are each a diagram of a second electrode portion in a modification of one embodiment. FIGS. 6A to 6C are each a plan view of the second electrode portion and its surrounding components in each modification in the cross section taken in the same manner as in FIG. 3C.

As shown in a first modification in FIG. 6A, the second electrode portion 1112b2 is cylindrical and has a cutout. In FIG. 6A, the cylindrical second electrode portion 1112b2 has a discontinuous portion 112c being a slit. The cylindrical second electrode portion 1112b2 may have multiple discontinuous portions, rather than a single discontinuous portion.

As shown in a second modification in FIG. 6B, multiple second electrode portions 1112b2 and 1112b3 may be arranged cylindrically. The second electrode portions 1112b2 and 1112b3 may be electrically coupled to the first electrode portion 1112b1. In other words, when the second electrode portions 1112b2 and 1112b3 are arranged concentrically, clearances may be left between the first electrode portion 1112b1 and the second electrode portion 1112b3 and between the second electrode portion 1112b2 and the second electrode portion 1112b3 to allow an RF signal to propagate. The inner cylindrical second electrode portion 1112b2 may have a height greater than or equal to the height of the outer cylindrical second electrode portion 1112b3. This enhances the performance of the second electrode portion 1112b2 as a shield, thus preventing or reducing occurrence of abnormal discharge in the gas supply hole 116 more effectively.

When the multiple second electrode portions 1112b2 and 1112b3 are arranged concentrically, the inner cylinder may have a cutout that does not overlap a cutout in the outer cylinder. As shown in a third modification in FIG. 6C, for example, discontinuous portions 112c and 112d in an inner cylindrical second electrode portion 1112b2 do not overlap discontinuous portions 112e and 112f in an outer cylindrical second electrode portion 1112b3 in the circumferential direction. Three or more second electrode portions may be arranged, rather than two.

In the example described with reference to FIGS. 3A to 6A, 6B, and 6C, the electrode structures prevent or reduce occurrence of abnormal discharge in the gas supply holes 116 for supplying a heat transfer gas into the space between the back surface of the substrate W and the central portion 111a. In some embodiments, the electrode structures are also applicable to the electrode structure for the electrostatic electrode 1113a and the electrode 1113b shown in FIG. 2. More specifically, the electrode 1113b may include a second electrode portion that serves as a shield in the same manner as the second electrode portion 1112b2. This can prevent or reduce occurrence of abnormal discharge in the gas supply hole for supplying a heat transfer gas into the space between the back surface of the edge ring or the ring assembly 112 and the annular portion 111b.

More specifically, the ESC according to the embodiment described above includes a support surface to support at least one of the substrate W or the edge ring, the electrostatic electrode that is below the support surface and electrostatically clamps at least one of the substrate W or the edge ring, the gas supply holes for supplying a heat transfer gas between at least one of the substrate W or the edge ring and the support surface, and the electrode that is located on a plane different from the plane on which the electrostatic electrode is located and is partially located between the electrostatic electrode and the gas supply holes.

The ESC according to the embodiment described above and the plasma processing apparatus including the ESC can prevent or reduce occurrence of abnormal discharge in the gas supply hole for supplying a heat transfer gas.

The electrode structure of the ESC 1111 according to the embodiment is also applicable to, for example, a through-hole for receiving a lifter pin for a substrate or a through-hole for receiving a lifter pin for an edge ring. More specifically, the substrate support 11 may have, in the central portion 111a, a through-hole for receiving a lifter pin for a substrate. The through-hole extends through the substrate support 11 from the upper surface of the substrate support 11 to the lower surface of the substrate support 11. The electrode 1112b may be at least partially located between the electrostatic electrode 1111b and the through-hole for receiving a lifter pin for a substrate. The substrate support 11 may have, in the annular portion 111b, a through-hole for receiving a lifter pin for an edge ring. The through-hole extends through the substrate support 11 from the upper surface of the substrate support 11 to the lower surface of the substrate support 11. The electrode 1113b may be at least partially located between the electrostatic electrode 1113a and the through-hole for receiving a lifter pin for an edge ring. The electrode structure is also applicable to a through-hole for supplying a heat transfer gas also serving as a through-hole for receiving a lifter pin.

The ESC and the plasma processing apparatus according to one embodiment described herein are illustrative in all aspects and should not be construed to be restrictive. The components in one embodiment may be altered or modified in various forms without departing from the spirit and scope of the appended claims. The features described in the above embodiments may have other configurations or may be combined unless any contradiction arises.

This application claims priority to Japanese Patent Application No. 2021-192399, filed with the Japanese Patent Office on Nov. 26, 2021, the entire contents of which are incorporated herein by reference.

### REFERENCE SIGNS LIST

1 Plasma processing apparatus
2 Controller
10 Plasma processing chamber
10s Plasma processing space
11 Substrate support
12 Plasma generator
13 Shower head
20 Gas supply
30 Power supply
31 RF power supply
31a First RF generator
31b Second RF generator
32a First DC generator
32b Second DC generator
111 Body
111a Central portion
111b Annular portion
112 Ring assembly
1110 Base
1111 Electrostatic chuck (ESC)
1111b Electrostatic electrode
1112b Electrode
1112b1 First electrode portion
1112b2, 1112b3 Second electrode portion

1. An electrostatic chuck, comprising:
a substrate support to support at least one of a substrate or an edge ring;
an electrostatic electrode inside the substrate support, the electrostatic electrode being configured to electrostatically clamp at least one of the substrate or the edge ring; and
an electrode inside the substrate support, the electrode being located on a plane different from a plane on which the electrostatic electrode is located,
wherein:
the substrate support has a through-hole extending through the substrate support from an upper surface of the substrate support to a lower surface of the substrate support, and
the electrode is at least partially located between the electrostatic electrode and the through-hole.

2. The electrostatic chuck according to claim 1, wherein:
the electrode includes:
a first electrode portion parallel to the electrostatic electrode; and
a second electrode portion electrically coupled to the first electrode portion, and
the second electrode portion is located between the electrostatic electrode and the through-hole.

3. The electrostatic chuck according to claim 2, wherein the second electrode portion surrounds the through-hole.

4. The electrostatic chuck according to claim 2, wherein the first electrode portion is located below the electrostatic electrode.

5. The electrostatic chuck according to claim 4, wherein a distance t2 between an upper end of the second electrode portion and a lower surface of the electrostatic chuck is greater than or equal to a distance t1 between the electrostatic electrode and the lower surface of the electrostatic chuck.

6. The electrostatic chuck according to claim 2, wherein the first electrode portion is located above the electrostatic electrode.

7. The electrostatic chuck according to claim 6, wherein a distance t4 between a lower end of the second electrode portion and a lower surface of the electrostatic chuck is less than or equal to a distance t3 between the electrostatic electrode and the lower surface of the electrostatic chuck.

8. The electrostatic chuck according to claim 2, wherein the second electrode portion is perpendicular to the first electrode portion.

9. The electrostatic chuck according to claim 8, wherein the second electrode portion has a cylindrical shape and includes at least one discontinuous portion.

10. The electrostatic chuck according to claim 9, wherein:
the second electrode portion includes at least two discontinuous portions so as to form a plurality of second electrode portions, and
each of the plurality of second electrode portions includes an inner cylindrical portion and an outer cylindrical portion, the inner cylindrical portion having a height greater than or equal to a height of the outer cylindrical portion.

11. A plasma processing apparatus, comprising:
a plasma processing chamber;
a base in the plasma processing chamber;
an electrostatic chuck on the base; and
a radio-frequency power supply electrically coupled to the base or electrically coupled to an electrode of the electrostatic chuck,
wherein:
the electrostatic chuck includes:
a substrate support to support at least one of a substrate or an edge ring;
an electrostatic electrode inside the substrate support, the electrostatic electrode being configured to electrostatically clamp at least one of the substrate or the edge ring; and
the electrode, the electrode being inside the substrate support and located on a plane different from a plane on which the electrostatic electrode is located,
the substrate support has a through-hole extending through the substrate support from an upper surface of the substrate support to a lower surface of the substrate support, and
the electrode is at least partially located between the electrostatic electrode and the through-hole.

12. The plasma processing apparatus according to claim 11, wherein:
the electrode includes:
a first electrode portion parallel to the electrostatic electrode; and
a second electrode portion electrically connected to the first electrode portion, and
the second electrode portion is located between the electrostatic electrode and the through-hole.

13. The plasma processing apparatus according to claim 12, wherein
the second electrode portion surrounds the through-hole.

14. The plasma processing apparatus according to claim 12, wherein
the first electrode portion is located below the electrostatic electrode.

15. The plasma processing apparatus according to claim 14, wherein
a distance t2 between an upper end of the second electrode portion and a lower surface of the electrostatic chuck is greater than or equal to a distance t1 between the electrostatic electrode and the lower surface of the electrostatic chuck.

16. The plasma processing apparatus according to claim 12, wherein
the first electrode portion is located above the electrostatic electrode.

17. The plasma processing apparatus according to claim 16, wherein
a distance t4 between a lower end of the second electrode portion and a lower surface of the electrostatic chuck is less than or equal to a distance t3 between the electrostatic electrode and the lower surface of the electrostatic chuck.

18. The plasma processing apparatus according to claim 12, wherein the second electrode portion is perpendicular to the first electrode portion.

19. The plasma processing apparatus according to claim 18, wherein
the second electrode portion has a cylindrical shape and includes at least one discontinuous portion.

20. The plasma processing apparatus according to claim 19, wherein:
the second electrode portion includes at least two discontinuous portions so as to form a plurality of second electrode portions, and
each of the plurality of second electrode portions includes an inner cylindrical portion and an outer cylindrical portion, the inner cylindrical portion having a height greater than or equal to a height of the outer cylindrical portion.
